(19) United States
(12) Patent Application Publication
(10) Pub. No.: US 2025/0383403 A1
(43) Pub. Date: Dec. 18, 2025

(54) DEVICE AND METHOD FOR DETERMINING A STATE IN A STACK OF FUEL CELLS OR ELECTROLYSIS CELLS OR IN A FUEL CELL OR ELECTROLYSIS CELL

(71) Applicant: Robert Bosch GmbH, Stuttgart (DE)

(72) Inventors: Manuel Joachim Schmidt, Ditzingen (DE); Veronika Schleper, Leinfelden-Echterdingen (DE); Lars Reichelt, Stuttgart (DE); Markus Ganser, Stuttgart (DE); Matthias Martin Hanauer, Leonberg (DE); Peter Wassermann, Weil Der Stadt (DE); Todor Doychev, Ludwigsburg (DE); Ulrich Sauter, Karlsruhe (DE)

(21) Appl. No.: 18/878,416

(22) PCT Filed: Jun. 22, 2023
(86) PCT No.: PCT/EP2023/066986

§ 371 Date: Dec. 23, 2024

(30) Foreign Application Priority Data
Jun. 28, 2022 (DE) 10 2022 206 492.5

(51) Int. Cl. G01R 31/367; G01R 31/396

(52) U.S. Cl. CPC G01R 31/367; G01R 31/396

(57) ABSTRACT

Device and method for determining a state (100) in a stack of fuel cells or electrolysis cells, or in a fuel cell or electrolysis cell, wherein membrane electrode unit and plates are provided, with a membrane electrode unit being arranged between each, wherein with a first model (102) inflows of process media are modeled from a periphery and outflows of a process product into the periphery as well as electrical input and output variables, wherein segments of the plates are modeled with a second model (104), wherein, with a third model (106), the membrane electrode unit or segments of the membrane electrode unit are modeled, wherein the first model (102) and the second model (104) have at least one coupling variable (108, 110), wherein the second model (104) and the third model (106) are coupled segmentally via at least one coupling variable (112,114), wherein at least one input variable of the first model (102) is specified, wherein the state (100) is determined from the at least one input variable, the first model (102), the second model (104) and the third model (106).

### BACKGROUND

The invention relates to a device and method for determining a state in a stack of fuel cells or electrolysis cells, or in a fuel cell or electrolysis cell.

When designing the polymer electrolyte membrane fuel cell, its behavior can be determined in a simulation that takes into account a geometry of the fuel cell. This simulation requires so many computing resources that it is desirable to provide an improved simulation for determining a state of the polymer electrolyte membrane fuel cell during an operation in the polymer electrolyte membrane fuel cell in a stack of polymer electrolyte membrane fuel cells.

### SUMMARY

A method for determining a state in a stack of fuel cells or electrolysis cells, or in a fuel cell or electrolysis cell, wherein at least one membrane electrode unit and plates are provided, with a membrane electrode unit being arranged between each, wherein with a first model inflows of process media from a periphery and outflows of a process product into the periphery as well as electrical input and output variables are modeled, wherein segments of the plates are modeled with a second model, wherein, with a third model, the membrane electrode unit or segments of the membrane electrode unit are modeled, wherein the first model and the second model have at least one coupling variable, wherein the second model and the third model are coupled segmentally via at least one coupling variable, wherein at least one input variable of the first model is specified, wherein the state is determined from the at least one input variable, the first model, the second model and the third model.

A membrane electrode unit can in particular be understood to mean at least one ion-conducting layer, the so-called membrane, and at least one electrode layer located on, and particularly applied to, one side of the ion-conducting layer. Preferably, an electrode layer is located on or applied to both sides of the ion-conducting layer, such that the ion-conducting layer (preferably sandwich-like) is located between the two electrode layers. Preferably, the membrane electrode unit may comprise further applied porous layers serving to distribute (input/output) the reaction media, the power and/or the heat. The at least one ion-conducting layer (membrane) may be designed, at least partially, as an ion-conducting polymer (e.g., for a PEM fuel cell, PEM electrolysis, AEM fuel cell, AEM electrolysis) and/or as an electrically non-conductive porous structure impregnated with an ion-conducting polymer and/or an ion-conducting liquid/solution (e.g., for liquid alkaline electrolysis or in the case of redox-flow batteries) and/or as a ceramic ion conductor (e.g., with SOFC/SOEC). The electrode layers are typically porous layers that perform the combined functions of ion transport, electron transport, liquid and/or gaseous reaction media transport, heat transport, and electrocatalysis. Depending on the technology, these combined functions may be comprised of any combination of electrocatalytically active materials (metals and/or metal oxides and/or ceramic materials) and/or electronically conductive (porous) carrier materials (metals, carbon materials, doped metal oxides, etc.) and/or ion conductors (polymeric ion conductors and/or liquid ion conductors and/or ceramic ion conductors). The membrane electrode unit may comprise further (mostly porous) functional layers, which serve to distribute the reaction media (transportation of the liquid and/or gaseous educts, removal of the liquid and/or gaseous products) and/or to transport electrons and heat. Depending on the application, at least one of the layers of the membrane electrode unit may also have mechanical functions, e.g., provision of a spring effect or mechanical support of adjacent layers.

The method may also advantageously be used to determine a state in a redox flow cell—or a redox flow cell stack. In particular, but not exclusively, the method is suitable for determining a state in an NT-PEM fuel cell, an HT-PEM fuel cell, an NT-PEM electrolysis cell, an HT-PEM electrolysis cell, an AEM fuel cell, an AEM electrolysis cell, an AEL electrolysis cell (classic liquid alkaline electrolysis), an SOFC, an SOEC, a MCFC/MCEC (Molten Carbonate Fuel Cell/Electrolysis Cell), PAFC/PAEC (Phosphoric Acid Fuel Cell/Electrolysis).

In the following sections, the method is explained essentially by the example of the PEM fuel cell, but is generally transferable to any fuel cells, electrolysis, and redox flow technologies.

Preferably, with the second model, a physical effect is modeled per segment or for a bundle of multiple segments. This additionally improves the simulation.

Preferably, with the third model, a physical effect of the membrane electrode unit is modeled or per segment of the membrane electrode unit. This allows simulation with particularly low requirements on the computing resources.

Preferably, during operation of the stack, the fuel cell or the electrolysis cell, a measurement is taken that characterizes operation, wherein the state is determined during operation depending on the measurement. This will affect the operation depending on a result of the simulation.

Preferably, during operation a variable is determined for operation, in particular an operating strategy, a control variable, or a regulating variable, depending on the state during operation, and the stack, the fuel cell, or the electrolysis cell, is controlled, as a function of the variable. This will affect the operation depending on a result of the simulation.

Preferably, depending on the state, in particular during operation, a variable is determined that characterizes an irreversible aging of the stack, the fuel cell or the electrolysis cell or a part thereof, or comprises a prediction for maintenance of the stack, the fuel cell or the electrolysis cell or a part thereof. The simulation allows this information to be determined about the state.

Preferably, depending on the state, a design parameter for the stack, fuel cell or electrolysis cell, or a part thereof, is determined. This allows a better design to be achieved faster.

Preferably, the first model, the second model and/or the third model comprise parameters, wherein training data is provided, each comprising at least one input variable for the first model and a reference for the state, wherein, with the at least one input variables from the training data, the respective states are determined and wherein the parameters are determined as a function of a deviation of the states from their respective reference from the training data, for which the deviation is as small as possible, and wherein the state is subsequently determined based on the specified at least one input variable of the first model.

A device, in particular a virtual sensor, for determining a state of a stack of fuel cells or electrolysis cells or in a fuel cell or electrolysis cell is configured to determine the state according to the method.

### BRIEF DESCRIPTION OF THE DRAWINGS

Further advantageous embodiments will become apparent from the following description and the drawing. The drawings show:

FIG. 1 shows a schematic representation of models for determining a state in a fuel cell stack,

FIG. 2 shows a schematic representation of a stack of a polymer electrolyte membrane fuel cell,

FIG. 3 shows a flowchart with steps in a method for determining a state in the stack.

### DETAILED DESCRIPTION

A polymer electrolyte membrane (PEM) fuel cell converts hydrogen and oxygen into water while generating electrical and thermal energy.

A solid oxide fuel cell converts a fuel, such as methane, while generating electrical and thermal energy.

The procedure is described in the following description for stacks of polymer electrolyte membrane fuel cells. A corresponding procedure is provided for other types of fuel cells, electrolysis cells or redox flow cells.

As noted above, the procedure is performed accordingly in particular for a solid oxide electrolysis cell or a polymer electrolyte membrane electrolysis cell.

The polymer electrolyte membrane fuel cell comprises a bipolar plate in a bipolar construction. The bipolar plate comprises a first electrode and a second electrode. Multiple bipolar plates are arranged serially between two end plates into a stack. A proton-conducting polymer membrane is arranged in the stack between two of the bipolar plates. The stack is held together by the end plates. The two outer bipolar plates of the stack are each electrically contacted by one of the end plates.

The polymer electrolyte membrane fuel cell comprises a monopolar plate in a monopolar construction instead of the bipolar plate. The monopolar plate comprises an electrode. Multiple monopolar plates are serially arranged between two end plates into a stack. In the example, a proton-conducting polymer membrane is arranged per fuel cell, which is surrounded by an insulator layer outside its active surface. The stack is held together by the end plates. The two outer monopolar plates of the stack are each electrically contacted by one of the end plates. In addition, electrical contacts for monopolar plates are provided, which are located within the stack.

The bipolar plate and monopolar plate are hereinafter referred to as a plate.

In the case of bipolar plates, the number of the plates is one greater than the number of the membrane electrode units. In the case of monopolar plates, the number of plates is twice as large as the number of membrane electrode units.

At least one channel is provided in the plate for a supply of a first process medium, in particular process air. A channel in the narrower sense and a channel in the broader sense can be understood as a continuous flow path, for example in the form of a path through an open porous material, such as in a PEM electrolysis cell.

At least one channel is provided in the plate for a supply of a second process medium, in particular process hydrogen.

At least one channel is provided in the plate for a coolant, in particular water.

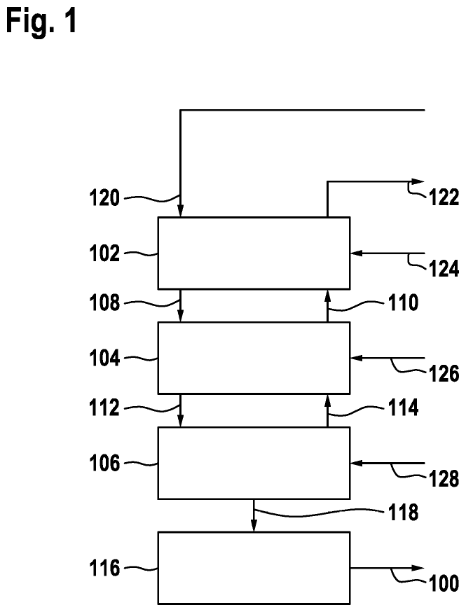

At least one channel is provided in the plate for removal of a process product, in particular process air and product water. In FIG. 1, exemplary models for determining a state 100 in the stack are shown. In FIG. 1, a first model 102 is for a periphery of the stack, as well as a second model 104 and a third model 106 is for at least one segment in the stack are shown. In one example, the segment comprises at least a part of an anode channel, at least a part of a membrane electrode unit, at least a part of a cathode channel and at least a part of a coolant channel. That is, the segment comprises two plates and a membrane electrode unit at least partially. In the example, the second model 104 models the at least a part of the anode channel, the at least a part of the cathode channel, and the at least a part of the coolant channel comprised of two plates. In the example, the third model 106 models at least a part of the membrane electrode unit.

The first model 102 is coupled to the second model 104 via at least a first coupling variable 108. The second model 104 is coupled to the first model 102 via at least a second coupling variable 110. In the example, the two plates in the second model 104 are amalgamated into one plate, wherein only one coupling variable is provided per direction for both plates, i.e. the first coupling variable 108 and the second coupling variable. It may be envisaged that in the second model 104, two segments are modeled per plate and each is coupled in each direction via a separate coupling variable.

The second model 104 is coupled to the third model 106 via at least a third coupling variable 112. The third model 106 is coupled to the second model 104 via at least a fourth coupling variable 114. In the example, a virtual sensor 116 is provided that senses the state 100. In the example, the virtual sensor 116 is coupled to the third model 106 via at least a fifth coupling variable 118. The first model 102 includes an input 120 for at least one input variable of the first model 102. The first model 102 includes an output 122 for outputting at least one output variable of the first model 102.

The second model 104 is configured to model physical operations, in particular transport processes, in the plate. The second model 104, in the example, models discrete segments in the plate. The transport processes take place, on the one hand, in a plane of the plate between the segments and, on the other hand, in a plane perpendicular to the plate between a segment or a bundle of segments from and to a membrane electrode unit. In the example, the transport processes in the plate are modeled in these planes with the second model 104. The transport processes in the membrane electrode unit are modeled with the third model 106.

For example, the second model 104 is configured to model heat transport, coolant transport, gas transport, and an electrical potential, each in a segment or a bundle of such segments.

In particular, media supply, supply of process media, in particular reaction gases, transport of process products, in particular liquid water, especially in a PEM fuel cell and/or heat, and electrical voltage are depicted by generalized resistors. These resistors are connected to resistor networks. The resistors may be linear or non-linear. Furthermore, the underlying resistors may be provided from physical models. For example, the physical models are discrete, e.g., by finite volume. For example, the physical models are pre-generated tables or data-based models.

A segment is a discretization point and comprises, for example, a channel of a particular channel length. The segment may also comprise multiple channels.

The physical processes within a segment are depicted, for example, via a representative element, for example a single channel or a representative channel bundle.

For example, within a segment, the following variables may be determined:
a gas concentration, a partial pressure, an electric voltage, a plate temperature, a gas temperature, a liquid water saturation, a coolant temperature, a coolant pressure. These variables are provided as examples. Other variables may also be determined.

For the second model 104, mathematical descriptions of the correlations may be used, e.g., for gas transport a description of two-phase flow according to Darcy or Poisseuille, for electric voltage a description according to Ohm's law, for plate temperature a description according to the thermal conduction equation, for the coolant a description of incompressible flow.

In the example, the third model 106 comprises a membrane electrode unit model per segment in the plane perpendicular to the plate. This membrane electrode unit model may be configured with different levels of complexity.

For example, the third model 106 is a one-dimensional model for approximatively determining inhomogeneous power distributions in the stack and determining a corresponding gas volume.

For example, the third model 106 is a two-dimensional model for determining internal states of the membrane electrode unit.

For example, the third model 106 is a three-dimensional model for evaluating processes in a microstructure of a membrane electrode unit. The processes are, for example, flow effects along a channel flow direction.

In one example, the membrane electrode unit model models membrane electrode unit physics in detail, wherein various internal states such as membrane moisture or saturations are automatically calculated. For example, the at least one fifth coupling variable 118 includes at least one of these internal states. Thus, for example, aging in a segment associated with this membrane electrode unit is determinable. By abstracting into segments, the membrane electrode unit model may be configured one-dimensionally, two-dimensionally or three-dimensionally.

The third model 106 models the membrane electrode unit physics in the case of a PEMFC, e.g., according to L. M. Pant et al., Electrochimica Acta, 326, 134963 (2019) or R. Vetter and J. O. Schumacher, Journal of Power Sources, 438, 227018 (2019) or A. A. Kulikovsky, Journal of The Electrochemical Society, 161, F263-F270 (2014).

The at least one third coupling variable 112 is, for example, a gas species concentration, a bipolar plate temperature, an electrical potential. For example, the at least one fourth coupling variable 114 is a material flow, a heat flow, an electrical flow. The third coupling variable 112 and/or the fourth coupling variable 114 couple the segments or bundles of segments to the membrane electrode unit models.

For a PEM fuel cell, an implementation of the third model 106 using partial differential equations, in which the third coupling variable 112 and the fourth coupling variable 114 are each configured for an anode and a cathode, is disclosed in Experimental parameter uncertainty in PEM Fuel Cell Modeling Part I: Scatter in material parameterization, R. Vetter and J. O. Schumacher, Journal of Power Sources, 438, 227018 (2019) arXiv: 1811.10091:

In equation (1), Ohm's law is solved, wherein the electrical potential represents the third coupling variable 112 and the electrical current represents the fourth coupling variable 114.

In equation (5), a heat equation is solved, wherein the temperature represents the third coupling variable 112 and the heat flow represents the fourth coupling variable 114.

In equation (13), the gas transport is calculated via the Maxwell Stefan equation, wherein the gas concentration represents the third coupling variable 112 and the material flow represents the fourth coupling variable 114.

In addition, in this formulation, a proton line in an ionomer is calculated with equation (1), as is water transfer in the ionomer with equation (9), adsorption/desorption with equation (22), evaporation/condensation with equation (23), reaction kinetics with equation (1), and contact resistances with equation (S24).

For example, the first model 102 includes a collection node for a resistor network. For example, the first model 102 is configured to map an inhomogeneity between cells of the stack. In this example, manifolds, i.e. inflows for process media and outflows for a process product and end plates of the stack are combined. It may be envisaged that one model is used for the inflow and outflow and a separate model is used for the end plates. It may be envisaged that separate models may be used for inflow, outflow and end plates. For example, the first model 102 is configured to account for thermal and electrical behavior of the entire stack. For example, the first model 102 is configured to model inhomogeneity of fluids across the channels.

In the example, the first model 102 is assigned to segments at the edge of the plate in addition to a membrane electrode unit model. Corresponding first and second coupling variables model a media supply, gas species flow, and gas temperature. For example, the media supply is modeled by mass flows from the periphery into the segment or from the segment into the periphery, an operating pressure, an outlet pressure, and/or a coolant temperature. This is done, for example, by numerically calculating fluid mechanics and then extracting generalized resistances.

In the example, the first model 102 includes at least one end plate model assigned to segments, in which the end plates are located. Corresponding first and second coupling variables model a translation of electrical requirements into electrical currents into the respective segments.

In order to calculate the entire stack with the aid of this discretization, several individual cells of the stack can be amalgamated into representative cell bundles. The cell bundle has altered properties as compared to the individual cell. For example, a resistance in the plane causes a compensating current that is illustrated. Additionally, the amalgamation impacts the first model 102. In this case, the first model 102 is configured with corresponding coupling variables for cell bundles. This creates a resistance network for the entire stack, which provides localized statements about internal states of the membrane electrode unit and the plates throughout the stack. An allowable cell count in a cell bundle is not limited. For example, the cell count is set according to the accuracy requirements of the application query.

The selection of cell bundle quantity and segment quantity is a tradeoff between accuracy and computational time. The segments may be rectangular, in particular square. A different geometric shape is also possible. In the example, a geometric requirement for the segments is that it allows for complete partitioning of the plate. In one example, the segments combine a plurality of channels into a channel bundle. The number of combined channels may comprise from one to all channels of the plates. In particular, the selection of only one channel bundle is sufficient if the expected performance differences transverse to a direction of flow in the channels are low or of low relevance for the question to be investigated. Otherwise, it may be necessary to consider a plurality of channel bundles. For example, a channel bundle includes 10 or more channels.

The cells at the edge of the stack are preferably integrated into smaller cell bundles in comparison to other cell bundles comprising cells in the middle of the stack, since the temperature profiles in particular differ there from those in the cells in the middle of the stack.

Further discretization is selected, for example, depending on use cases:

For simple questions such as polarization curves or operational strategies with non-aging-relevant states, a selection of e.g. 5-20 segments along the flow channels, as well as, for example, 1-10 cell bundles, is sufficient.

For age-relevant questions in which local internal states of a membrane electrode unit must be mapped very accurately, a segment number of e.g. 100 and more segments along the flow direction of the channels is also advantageous.

The first model 102, the second model 104, and the third model 106 include parameters. The models particularly comprise coupled partial differential equations or are determined as analytical functions or as a neural network or multiple neural networks. The parameters define the models, i.e. the differential equations or the analytical functions or neural networks. The differential equations, analytical functions, and neural networks model electrochemical or physical effects in the stack. The differential equations and analytical functions include electrochemical or physical variables. The differential equations and analytical functions may also include state variables for which there is neither an electrochemical nor a physical equivalent in the stack. The neural networks include inputs for electrochemical or physical variables and outputs for electrochemical or physical variables. The differential equations, the analytical functions and the neural networks, respectively, are coupled via the coupling variables.

Depending on the state 100 to be modeled, the differential equations and neural networks may comprise different variables, coupling variables and/or parameters. Examples of the variables and the coupling variables will be described below. In one example, the models, i.e., the differential equations, the analytical functions, and the neural networks, respectively, are fully solved to determine the state 100. In one example, an explicit coupling may be provided or multiple explicit couplings may be provided.

The first model 102 optionally includes an interface 124 for data input for the first model 102. The second model 104 optionally includes an interface 126 for data input for the second model 104. The third model 106 optionally includes an interface 128 for data input for the third model 106.

With these interfaces, the parameters of the respective models can be changed for data input.

Training may be provided for the data input. Training data is provided during training, with each piece of data comprising at least one input variable for the first model 102 and a reference for the state 100. The reference indicates which state 100 is to be modeled with the models and the respective input variables.

With the at least one input variables from the training data, the respective states 100 are determined.

For example, the parameters are determined based on a deviation of the states 100 from their respective reference from the training data.

For example, by an optimization method that minimizes the deviation, the parameters for which the deviation is as small as possible are determined. The deviation is as small as possible if, for example, a mean of the deviations is minimal for the training data.

In an inference, the state 100 is subsequently determined depending on the parameters determined in the training and a specified at least one input variable of the first model 102.

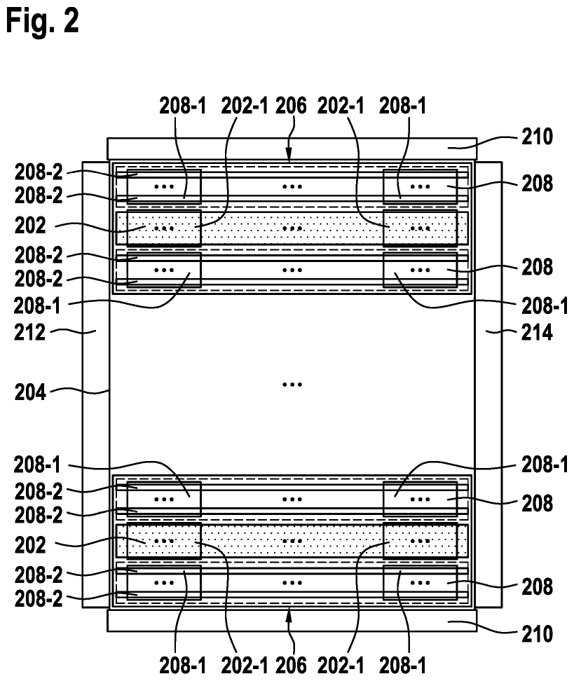

FIG. 2 schematically shows membrane electrode units 202 arranged in a fuel cell stack 204. The stack 204 has two ends 206 between which plates 208 are arranged. The stack 204 is electrically contacted at each of its ends 206 by an end plate 210. These are located on opposite end faces of the stack 204. A first of the plates 208 of the stack 204 is electrically connected to a first of the end plates 210 and a last of the plates 208 of the stack 204 is electrically connected to a second of the end plates 210.

With the second model 104, segments 208-1 of the plate 208 are modeled. The plates 208 include channels 208-2. Each segment 208-1 includes a part of each of the channels 208-2, or parts of multiple channels 208-2, respectively.

An inflow 212 is located on the side of stack 204, through which channels 208-2 of the stack 204 are supplied with process media. A process product is led out of channels 208-2 of the stack 204 via an outflow 214. Outflow 214 is located on a side of stack 204 opposite inflow 212.

With the first model 102, inflows into or outflows from the stack 204 are modeled depending on at least one input variable of the first model 102.

With the first model 102, electrical input and output variables of the stack 204 are modeled depending on at least one input variable of the first model 102.

The segments 208-1 of the plates 208 of the stack 204 are modeled in the second model 104.

With the second model 104, physical effects in the segments 208-1 are modeled.

With the third model 106, physical effects are modeled in membrane electrode elements 202 or in segments 202-1 of the membrane electrode elements 202. For example, the segments 202-1 of a membrane electrode element 202 are each assigned to a segment 208-1 of the two plates 208 adjacent to the membrane electrode element 202, wherein segments 202-1 arranged adjacently to each other may be assigned to one another.

These segments may be decoupled from or coupled to each other. In the example, the number of segments in the second model 104 is equal to the number of segments in the third model 106. This represents a conforming discretization. The segments in the second model 104 are connected to the segments in the third model 106 via, for example, the third coupling variable 112. The segments in the third model 104 are connected to the segments in the second model 106 via, for example, the fourth coupling variable 114. The number of segments in the second model 104 may differ from the number of segments in the third model 106. This represents a non-conforming discretization. The segments in the second model 104 are connected to the segments in the third model 106 via, for example, a correspondingly adjusted third coupling variable 112. The segments in the third model 106 are connected to the segments in the second model 104 via, for example, a correspondingly adjusted fourth coupling variable 114.

In the example, the third model 106 includes a one-dimensional, two-dimensional, or three-dimensional model for each segment 202-1, with which boundary conditions are modeled from the segment 208-1 of the plate 208 assigned to that segment 202-1. This achieves significant computational time savings.

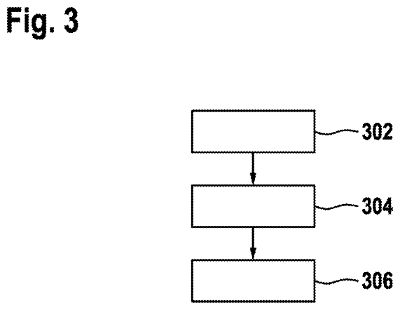

In FIG. 3, steps are described in a method for determining the state 100 in the stack 204. The method discussed below with reference to the polymer electrolyte membrane fuel cell may be applied analogously to any fuel cells, electrolysis, and redox flow technologies.

In a step 302, at least one input variable of the first model 102 is determined, e.g., from a specified measurement on a membrane electrode unit installed in the polymer electrolyte membrane fuel cell. The measurement is taken in one example during operation of the polymer electrolyte membrane fuel cell. In the example, the measurement characterizes the operation of the polymer electrolyte membrane fuel cell, i.e. the measurement comprises at least one measurable variable that characterizes the operation.

In a step 304, the state 100 is determined with the at least one input variable, the first model 102, the second model 104, and the third model 106. For example, the state 100 is sensed with the virtual sensor 116.

In the example, the virtual sensor 116 senses the at least one fifth coupling variable 118. In the example, the first model 102, the second model 104, and the third model 106 are solved in a fully coupled manner for the at least one input variable of the first model 102. The models are coupled over the respective coupling variables.

Subsequently, a step 306 is carried out.

In step 306, in one example, the at least one output variable of the first model 102 is output. For example, the output variable is a calculated variable for a variable included in the measurement. It may be envisaged that these variables are aligned to one another.

In step 306, in one example, a variable for operating the stack 204, particularly an operating strategy, a control variable, or a regulating variable, is determined depending on the state 100, and the stack 204 is controlled based on the variable. For example, the variable is determined during operation of the stack 204 depending on a measurement of the stack 204 taken during operation of the stack 204. For example, during its operation, the stack 204 is controlled with the variable.

In step 306, in one example, depending on the state 100 of the stack 204, a variable is determined that characterizes an irreversible aging of the stack 204 or a part thereof. State 100 and/or the variable is determined, for example, during operation.

In step 306, in one example, depending on the state 100 of the stack 204, a variable is determined that predicts maintenance of the stack 204 or a part thereof. State 100 and/or the variable is determined, for example, during operation.

In step 306, in one example, a design parameter for the stack 204 or a part thereof is determined depending on the state 100 of the stack 204. For example, steps 302 to 306 are repeated in a design process many times, wherein a plurality of design parameters are determined. For example, different parameters of the second model 104 and/or the third model 106 simulate different designs.

For example, state 100 is determined depending on the at least one input variable for the first model 102.

Exemplary applications for example states are provided below. In the example, with respect to stack 204, a distinction is made between a fuel cell stack of the polymer electrolyte membrane fuel cell and an electrolysis stack of the polymer electrolyte membrane electrolysis cell. The fuel cell stack comprises fuel cells. The electrolysis stack comprises electrolysis cells.

For a redox-flow battery, a solid oxide fuel cell or a solid oxide electrolysis cell, proceed accordingly.

For example, the states relate to the fuel cell stack, fuel cells therein, or parts thereof. In addition to the parts of the fuel cell stack already described, the fuel cell stack comprises, for example, at least one gas diffusion layer, at least one microporous layer, at least one catalyst layer, at least one inlet for the first process medium, at least one inlet for the second process medium, at least one membrane, and/or at least one gas diffusion medium.

For example, state 100 is an internal state of the fuel cell stack.

For example, the following variables are input variables of the fuel cell stack or indicate the internal state of the fuel cell stack:
a gas composition of anode gas,
a gas composition of cathode gas,
a gas pressure of anode gas at an outlet in the fuel cell stack,
a gas mass flow of anode gas at an outlet in the fuel cell stack,
a gas pressure of cathode gas at an outlet in the fuel cell stack,
a gas mass flow of cathode gas at an outlet in the fuel cell stack,
a gas pressure of anode gas at an inlet in the fuel cell stack,
a gas mass flow of anode gas at an inlet in the fuel cell stack,
a gas pressure of cathode gas at an inlet in the fuel cell stack,
a gas mass flow of cathode gas at an inlet in the fuel cell stack,
a gas temperature of anode gas
a gas temperature of cathode gas,
a temperature of the coolant,
a mass flow of the coolant,
an electrical voltage generated by the fuel cell stack,
an electrical current generated by the fuel cell stack.

The first model 102 optionally includes a thermal model that models an ambient condition of the fuel cell stack, e.g., a temperature and/or a relative humidity of the ambient air of the fuel cell stack.

For example, state 100 is an inhomogeneity of an internal state of a fuel cell in the fuel cell stack.

For example, state 100 is an inhomogeneity of an internal state of at least one channel for gas, at least one channel for coolant, or a structure of the plate in the fuel cell stack.

For example, state 100 is an operational state of the membrane electrode unit of a fuel cell or multiple fuel cells of the fuel cell stack, for example, the operational state of at least one gas diffusion carrier, at least one microporous layer, at least one catalyst layer, and/or at least one polymer electrolyte membrane of the fuel cell.

State 100 is determined, for example, for drying, for a brief overload, or during transient operation of the fuel cell.

For example, state 100 is a condition within a fuel cell or within the fuel cell stack for water management in the fuel cell stack, e.g., a temperature, a gas composition, a saturation, a liquid water content, or a water transfer through the polymer electrolyte membrane fuel cell.

State 100 is, for example, a state that occurs upon starting or stopping the fuel cell stack.

State 100 is, for example, a state that is important for a frozen start. In one example, in particular, depending on a temperature, the frozen start is detected and the state 100 is sensed for the frozen start.

For example, state 100 is a local state in the fuel cell stack. In one example, depending on the state 100, an impact of production variations on the local state is determined.

In one example, state 100 is a local temperature distribution or gas composition within a fuel cell and/or the fuel cell stack.

In one example, the state 100 is a local saturation within a fuel cell and/or the fuel cell stack in at least one porous layer, in particular at least one gas diffusion layer, at least one microporous layer, at least one catalyst layer, and/or at least one gas channel.

In one example, state 100 is a local current density distribution or a local voltage distribution within a fuel cell and/or the fuel cell stack.

In one example, the state 100 is a local water content in a membrane of the fuel cell stack.

In one example, the state 100 is at least one local potential in at least one catalyst layer of the fuel cell stack.

In one example, state 100 is a local contribution of a local reaction to an overall voltage or current that the fuel cell stack provides. For example, the state 100 is sensed for various local reactions and, depending on the sensed states, the total voltage and the total current is determined.

In one example, the state 100 is a local irreversible aging, particularly an ionomer aging in the fuel cell stack. Irreversible aging is, for example, catalyst aging of a catalyst layer of the fuel cell stack and/or membrane aging in at least one membrane of the fuel cell stack and/or aging in at least one gas diffusion carrier of the fuel cell stack and/or aging in at least one microporous layer of the fuel cell stack.

In one example, the state 100 is a local irreversible aging in a membrane electrode unit. For example, for the membrane electrode unit, different states 100, i.e., different local irreversible agings, are sensed and depending on the sensed states, the irreversible aging of the membrane electrode unit is determined.

In one example, the state 100 is sensed and a particularly optimal operating strategy is determined depending on the state 100. For example, the operating strategy is determined taking into account an efficiency and/or a useful life of the fuel cell stack.

In one example, an optimal design of the fuel cell stack to achieve a desired efficiency and/or useful life is determined depending on the state 100.

In one example, the state 100 is determined for a plurality of different designs of the fuel cell stack and the optimal design is selected from the plurality depending on the state 100. This enables a cost-efficient design process.

In one example, an actual state of the fuel cell stack is determined depending on the state 100. For example, the state 100 is determined depending on a measurement of the fuel cell stack.

For example, the actual state is a state of the fuel cell stack during its operation. For example, state 100 is determined depending on a measurement of the fuel cell stack that is sensed during its operation. For example, the measurement during operation of the fuel cell stack is sensed and the state 100 is determined during operation of the fuel cell stack depending on the measurement.

In one example, a control variable or regulating variable for operating the fuel cell stack is determined depending on the state 100. The control variable or regulating variable is determined, for example, during operation of the fuel cell stack. The control variable or the regulating variable is determined, for example, depending on the measurement. For example, the measurement during operation of the fuel cell stack is sensed, the state 100 is determined during operation of the fuel cell stack depending on the measurement, the control variable or regulating variable is determined depending on the state 100 during operation of the fuel cell stack, and the fuel cell stack is controlled as a function of the control variable or regulating variable.

In one example, a fuel cell stack maintenance prediction is determined depending on the state 100.

In one example, depending on state 100, a prediction for an adaptive change of at least one operating condition is determined that can affect a useful life and/or performance during operation of the fuel cell stack.

In one example, based on the state 100 with a system model modeling a system in which the fuel cell stack is operating, at least one input variable for the fuel cell stack is estimated, e.g., a gas composition.

In the following sections, application cases relating to electrolysis in the electrolysis stack are described. An electrolysis stack comprises electrolysis cells. The electrolysis stack comprises an electrolysis stack that comprises the electrolysis cells in the example.

For example, state 100 is an internal state of the electrolysis stack.

The following variables are, for example, input variables for the electrolysis stack or indicate the internal state of the electrolysis stack:
a composition of anode and cathode fluids,
a pressure of an anode fluid at an inlet of the electrolysis stack,
a pressure of an anode fluid at an outlet of the electrolysis stack,
a pressure of a cathode fluid at an inlet of the electrolysis stack,
a pressure of a cathode fluid at an outlet of the electrolysis stack,
a mass flow of the anode fluid at the inlet of the electrolysis stack,
a mass flow of the anode fluid at the outlet of the electrolysis stack,
a mass flow of the cathode fluid at the inlet of the electrolysis stack,
a mass flow of the cathode fluid at the outlet of the electrolysis stack,
a temperature of the anode fluid,
a temperature of the cathode fluid,
an electrical voltage generated by the electrolysis stack,
an electrical current generated by the electrolysis stack.

For example, state 100 is an inhomogeneity of an internal state of an electrolysis cell in the electrolysis cell stack.

For example, state 100 is an inhomogeneity of an internal state of at least one channel for gas, at least one channel for coolant, or a structure of the plate in the electrolysis cell stack.

For example, state 100 is an operating state of the membrane electrode unit of an electrolysis cell or multiple electrolysis cells, for example, the operating state of at least one porous transport layer, at least one catalyst layer, and/or the polymer electrolyte membrane electrolysis cell.

For example, the polymer electrolyte membrane electrolysis cell is part of an electrolyzer. State 100 is determined, for example, during transient operation of the electrolyzer.

State 100 is, in one example, an operating state of the electrolysis cell stack, particularly for load balancing, and is determined during overload, for example, during operation of the electrolysis cell stack.

The state 100 is, in one example, an operating state of the electrolysis cell stack that occurs on startup, i.e. start, or shutting down, i.e. stopping, the electrolyzer.

For example, state 100 is a local state in the electrolysis cell stack. In one example, depending on the state 100, an impact of production variations on the local state is determined.

In one example, state 100 is a local temperature distribution in the electrolysis cell stack or in an electrolysis cell.

In one example, the state 100 is a local fluid composition within an electrolysis cell and/or the electrolysis cell stack.

In one example, the state 100 is a local saturation, i.e. a distribution of liquid and gas phases, in at least one porous layer, in particular in at least one porous transport layer, at least one catalyst layer, and/or in at least one of the channels for a fluid.

In one example, state 100 is a local current density distribution or a local voltage distribution.

In one example, state 100 is a local current density distribution or a local voltage distribution within an electrolysis cell and/or the electrolysis cell stack.

In one example, the state 100 is at least one local potential in at least one catalyst layer of the electrolysis cell stack.

In one example, state 100 is a local contribution of a local reaction to an overall voltage or current that the electrolysis cell stack provides. For example, the state 100 is sensed for various local reactions and, depending on the sensed states, the total voltage and the total current is determined.

In one example, the state 100 is a local irreversible aging, particularly ionomer aging in the electrolysis cell stack. Irreversible aging is, for example, catalyst aging of a catalyst layer of the electrolysis cell stack and/or membrane aging in at least one membrane of the electrolysis cell stack and/or aging in at least one gas diffusion carrier of the electrolysis cell stack and/or aging in at least one microporous layer of the electrolysis cell stack.

In one example, the state 100 is a local irreversible aging in a membrane electrode unit. For example, for the membrane electrode unit, different states 100, i.e., different local irreversible agings, are sensed and depending on the sensed states, the irreversible aging of the membrane electrode unit is determined.

In one example, the state 100 is sensed and a particularly optimal operating strategy is determined depending on the state 100. For example, the operating strategy is determined taking into account an efficiency and/or a useful life of the electrolysis cell stack.

In one example, an optimal design of the electrolysis cell stack for achieving a desired efficiency and/or useful life is determined depending on the state 100.

In one example, the state 100 is determined for a plurality of different designs of the electrolysis cell stack and the optimal design is selected from the plurality depending on the state 100. This enables a cost-efficient design process.

In one example, an actual state of the electrolysis cell stack is determined depending on the state 100. For example, the state 100 is determined depending on a measurement of the electrolysis cell stack.

For example, the actual state is a state of the electrolysis cell stack during its operation. For example, the state 100 is determined depending on a measurement of the electrolysis cell stack that is sensed during its operation. For example, the measurement is sensed during operation of the electrolysis cell stack and the state 100 is determined during operation of the electrolysis cell stack depending on the measurement.

In one example, a control variable or regulating variable for operating the electrolysis cell stack is determined depending on the state 100. The control variable or regulating variable is determined, for example, during operation of the electrolysis cell stack. The control variable or the regulating variable is determined, for example, depending on the measurement. For example, the measurement is taken during operation of the electrolysis cell stack, the state 100 is determined during operation of the electrolysis cell stack depending on the measurement, the control variable or the regulating variable is determined depending on the state 100 during operation of the electrolysis cell stack, and the electrolysis cell stack is controlled as a function of the control variable or the regulating variable.

In one example, an electrolysis cell stack maintenance prediction is determined depending on the state 100.

In one example, depending on state 100, a prediction for an adaptive change of at least one operating condition is determined that can affect a useful life and/or performance during operation of the electrolysis cell stack.

In one example, based on the state 100 with a system model modeling a system in which the electrolysis cell stack is operating, at least one input variable for the electrolysis cell stack is estimated, e.g., water conductivity or a circulating residual gas. The conductivity of the water changes, e.g., due to contamination during operation.

1. A method for determining a state (100) in a stack (204) of fuel cells or electrolysis cells, or in a fuel cell or electrolysis cell, wherein at least one membrane electrode unit (202) and plates (208) are provided, with a membrane electrode unit (202) being arranged between each, wherein with a first model (102) inflows of process media from a periphery and outflows of a process product into the periphery as well as electrical input and output variables are modeled, wherein segments (208-1) of the plates (208) are modeled with a second model (104), wherein, with a third model (106), the membrane electrode unit (202) or segments (202-1) of the membrane electrode unit (202) are modeled, wherein the first model (102) and the second model (104) have at least one coupling variable (108, 110), wherein the second model (104) and the third model (106) are coupled segmentally via at least one coupling variable (112, 114), wherein at least one input variable of the first model (102) is specified (302), wherein the state (100) is determined (304) from the at least one input variable, the first model (102), the second model (104) and the third model (106).

2. The method according to claim 1, wherein with the second model (104) a physical effect is modeled per segment (208-1), or for a bundle of several segments (208-1).

3. The method according to claim 1, wherein with the third model (106) a physical effect of the membrane electrode unit (202) is modeled or per segment (202-1) of the membrane electrode unit (202).

4. The method according to claim 1, wherein during operation of the stack (204), the fuel cell, or the electrolysis cell, a measurement is taken (302) characterizing the operation, wherein the state (100) is determined (304) during operation dependent on the measurement.

5. The method according to claim 4, wherein during operation a variable is determined for operation depending on the state (100) during operation, and the stack (204), the fuel cell, or the electrolysis cell, is controlled (306), as a function of the variable.

6. The method according to claim 4, wherein, depending on the state (100), a variable is determined (306) that characterizes an irreversible aging of the stack (204), the fuel cell or the electrolysis cell or a part thereof, or comprises a prediction for maintenance of the stack (204), the fuel cell or the electrolysis cell or a part thereof.

7. The method according to claim 1, wherein, depending on the state (100), a design parameter for the stack (204), fuel cell or electrolysis cell or a part thereof is determined (306).

8. The method according to claim 1, wherein the first model (102), the second model (104) and/or the third model (106) comprise parameters, wherein training data is provided, each comprising at least one input variable for the first model (102) and a reference for the state (100), wherein, with the at least one input variables from the training data, the respective states (100) are determined and wherein the parameters are determined as a function of a deviation of the states (100) from their respective reference from the training data, for which the deviation is as small as possible, and wherein the state (100) is subsequently determined based on the specified at least one input variable of the first model (102).

9. A device for determining a state (100) of a stack of fuel cells or electrolysis cells, or in a fuel cell or electrolysis cell (202), wherein the device is configured to determine the state (100) according to the method of claim 1.

10. A non-transitory, computer-readable medium containing instructions that when executed by a computer, cause a the computer to determine a state (100) in a stack (204) of fuel cells or electrolysis cells, or in a fuel cell or electrolysis cell, wherein at least one membrane electrode unit (202) and plates (208) are provided, with a membrane electrode unit (202) being arranged between each, wherein with a first model (102) inflows of process media from a periphery and outflows of a process product into the periphery as well as electrical input and output variables are modeled, wherein segments (208-1) of the plates (208) are modeled with a second model (104), wherein, with a third model (106), the membrane electrode unit (202) or segments (202-1) of the membrane electrode unit (202) are modeled, wherein the first model (102) and the second model (104) have at least one coupling variable (108, 110), wherein the second model (104) and the third model (106) are coupled segmentally via at least one coupling variable (112, 114), wherein at least one input variable of the first model (102) is specified (302), wherein the state (100) is determined (304) from the at least one input variable, the first model (102), the second model (104) and the third model (106).
